(19) United States
(12) Patent Application Publication
(10) Pub. No.: US 2025/0393451 A1
(43) Pub. Date: Dec. 25, 2025

(54) DISPLAY DEVICE, MANUFACTURING METHOD THEREOF, AND ELECTRONIC DEVICE HAVING DISPLAY DEVICE

(71) Applicant: Samsung Display Co., Ltd., Yongin-si (KR)

(72) Inventor: Cha-Dong KIM, Yongin-si (KR)

(21) Appl. No.: 19/173,699

(22) Filed: Apr. 8, 2025

(30) Foreign Application Priority Data
Jun. 25, 2024 (KR) 10-2024-0083183
Jul. 8, 2024 (KR) 10-2024-0089864

(51) Int. Cl. H10K 59/80; B60K 35/22; H10K 59/12; H10K 102/00

(52) U.S. Cl. CPC H10K 59/8792; H10K 59/1201; H10K 59/877; H10K 59/878; B60K 35/22; B60K 2360/1523; H10K 2102/351

(57) ABSTRACT

A display device includes: a substrate; a light emitting diode on the substrate and including a light emitting layer; a pixel defining layer having an opening corresponding to the light emitting layer; an encapsulation layer on an upper portion of the pixel defining layer and the light emitting layer; light blocking linear patterns on an upper portion of the encapsulation layer, extending in a first direction, each including a protruding portion; a first organic layer between adjacent light blocking linear patterns; and a second organic layer covering upper surfaces of the light blocking linear patterns and having a lower refractive index than the first organic layer.

### CROSS-REFERENCE TO RELATED APPLICATIONS

The present application claims priority to and the benefit of Korean Patent Application No. 10-2024-0083183, filed on Jun. 25, 2024, in the Korean Intellectual Property Office, and Korean Patent Application No. 10-2024-0089864, filed on Jul. 8, 2024, in the Korean Intellectual Property Office, the entire content of each of which is incorporated herein by reference.

### BACKGROUND

### 1. Field

One or more embodiments of the present disclosure relate to a display device, a manufacturing method thereof, and a vehicle and an electronic device each including the display device.

### 2. Description of the Related Art

Display devices, including liquid crystal displays (LCDs) and organic light-emitting diodes (OLEDs), are used to display images. These display devices have been extensively utilized in electronic devices such as mobile phones, navigation systems, digital cameras, electronic books, portable gaming devices, and/or various other suitable terminals.

Furthermore, display devices may be employed in various other suitable fields beyond electronic devices. For example, in vehicles, related art analog dashboards and center fascias (displaying analog data) are being replaced (developed) to instead display digital data using these display devices.

### SUMMARY

One or more aspects of embodiments of the present disclosure are directed toward a display device that may prevent or reduce light emitted by the display device from being emitted in (to) a specific direction, to increase light efficiency.

One or more aspects of embodiments of the present disclosure are directed toward a display device that may prevent or reduce light emitted from the display device used in a vehicle from being directed to the eyes of a driver, to thereby facilitate driving.

One or more aspects of embodiments of the present disclosure are directed toward a display device that may prevent or reduce, when used in a vehicle, from being reflected on a windshield of the vehicle and from obstructing views of a driver at night. For example, an aspect is directed toward a display device that may prevent or reduce reflections on a vehicle's windshield when used in a vehicle, thereby preventing obstruction of the driver's view at night.

According to one or more embodiments of the present disclosure, a display device includes: a substrate; a light emitting diode on (e.g., arranged on) the substrate and including a light emitting layer; a pixel defining layer having an opening corresponding to the light emitting layer; an encapsulation layer on (e.g., arranged on) an upper portion of the pixel defining layer and the light emitting layer; light blocking linear patterns on (e.g., arranged on) an upper portion of the encapsulation layer, extending in a first direction, each including a protruding portion; a first organic layer between (e.g., arranged between) adjacent light blocking linear patterns; and a second organic layer covering upper surfaces of the light blocking linear patterns and having a lower refractive index than the first organic layer.

The light blocking linear patterns may each include a main body and the protruding portion, the main body and the protruding portion respectively have a columnar shape, and the protruding portion is on (e.g., arranged on) a portion of an upper surface of the main body, and at least one of the light blocking linear patterns may traverse (cross) the light emitting layer and may overlap the light emitting layer in a plan view.

The protruding portion may have a height of equal to or greater than about 1 micrometer (μm) and equal to or less than about 5 μm and may have a height of equal to or greater than about ¼ and equal to or less than about ¾ of an entire height of the light blocking linear pattern (e.g., a corresponding light blocking linear pattern), and the protruding portion may have a width of equal to or greater than about ¼ and equal to or less than about ¾ of a width of the main body.

The second organic layer may include a first portion and a second portion, the first portion may have the same width as the main body of the light blocking linear pattern (e.g., a corresponding light blocking linear pattern), and may be on (e.g., arranged on) an upper surface of the protruding portion of the light blocking linear pattern (e.g., a corresponding light blocking linear pattern), and the second portion may protrude towards the substrate from the first portion corresponding to the protruding portion of the light blocking linear pattern (e.g., the corresponding light blocking linear pattern).

The first organic layer may have a refractive index of greater than 1.5, and the second organic layer may have the refractive index of equal to or less than 1.5.

A height of the main body of the light blocking linear pattern may be equal to or greater than about 4 μm and equal to or less than about 30 μm, and the entire height of the light blocking linear pattern (e.g., see BL of FIG. 4) up to the protruding portion (e.g., see BL-2 of FIG. 4) may be equal to or greater than about 5 μm and equal to or less than about 35 μm, an entire height of the second organic layer up to the second portion may be equal to or greater than about 6 μm and equal to or less than about 10 μm, and a height of the first portion of the second organic layer may be equal to or greater than 0 μm and equal to or less than about 5 μm, an entire height of the first organic layer may be equal to or greater than about 10 μm and equal to or less than about 40 μm, the width of the main body of the light blocking linear pattern may be equal to or greater than about 1 μm and equal to or less than about 5 μm, and a width of the first organic layer may be equal to or greater than about 4 μm and equal to or less than about 10 μm, and a width of a portion on which the first organic layer may be arranged to a width of a portion on which the first organic layer may not be arranged has a ratio of equal to or greater than 3:1 and equal to or less than 5:1.

In one or more embodiments, the second organic layer may further include scatterers with a different refractive index from that of the second organic layer, and the scatterers may include at least one of titanium dioxide (TiO₂), silicon dioxide (SiO₂), zirconium oxide (ZrO₂), aluminum oxide (Al₂O₃), hollow silica, an acrylate-based material, or a silicon-based material.

In one or more embodiments, the display device may further include a reflective layer between (e.g., arranged between) the light blocking linear pattern and the first organic layer and between the second organic layer and the first organic layer, wherein the reflective layer may have a thickness of equal to or greater than about 200 angstroms (Å) and equal to or less than about 500 Å.

The reflective layer may be on (e.g., arranged on) a bottom surface of the light blocking linear pattern.

The reflective layer may have a protruding structure formed higher than an upper surface of the second organic layer or an upper surface of the first organic layer.

According to one or more embodiments of the present disclosure, a method for manufacturing a display device includes: forming a first organic layer on a substrate on which an encapsulation layer is formed, the first organic layer being an upper transparent layer; forming a hard mask pattern on the upper transparent layer; forming an opening in the first organic layer by etching the first organic layer exposed by the hard mask pattern; forming a reflective layer in the opening of the first organic layer by a chemical vapor deposition method; removing the hard mask pattern; forming a light blocking linear pattern including a protruding portion with an organic material including a black pigment on the reflective layer formed in the opening of the first organic layer; and forming a second organic layer in the opening of the first organic layer and on an upper portion of the light blocking linear pattern.

The light blocking linear pattern may provide different exposed amounts depending on positions of the organic material, and may be developed to include a protruding portion.

In the forming of a reflective layer, the reflective layer may be formed on the hard mask pattern, and in the removing of the hard mask pattern, the reflective layer on the hard mask pattern may be removed together with the hard mask pattern.

The light blocking linear pattern may include a main body and the protruding portion, the main body and the protruding portion each may have a columnar shape, and the protruding portion may be on (e.g., arranged on) a portion of an upper surface of the main body, the second organic layer may include a first portion and a second portion, the first portion may have the same width as the main body of the light blocking linear pattern, and may be on (e.g., arranged on) an upper surface of the protruding portion of the light blocking linear pattern, the second portion may protrude downward from the first portion corresponding to the protruding portion of the light blocking linear pattern, and the reflective layer may be between (e.g., arranged between) the light blocking linear pattern and the first organic layer, between the second organic layer and the first organic layer, and on a bottom surface of the light blocking linear pattern.

According to one or more embodiments of the present disclosure, an electronic device or a vehicle includes a light emitting display device, wherein the light emitting display device includes: a substrate; a light emitting diode on (e.g., arranged on) the substrate and including a light emitting layer; a pixel defining layer having an opening corresponding to the light emitting layer; an encapsulation layer on (e.g., arranged on) an upper portion of the pixel defining layer and the light emitting layer; light blocking linear patterns on (e.g., arranged on) an upper portion of the encapsulation layer, extending in a first direction, each (of the light blocking linear patterns) including a protruding portion; a first organic layer between (e.g., arranged between) adjacent light blocking linear patterns; and a second organic layer covering upper surfaces of the light blocking linear patterns and having a lower refractive index than the first organic layer.

In one or more embodiments, the electronic device or the vehicle may further include a second light emitting display device, and the second light emitting display device may include: a substrate; a light emitting diode on (e.g., arranged on) the substrate and including a light emitting layer; a pixel defining layer having an opening corresponding to the light emitting layer; an encapsulation layer on (e.g., arranged on) an upper portion of the pixel defining layer and the light emitting layer; second light blocking linear patterns on (e.g., arranged on) an upper portion of the encapsulation layer, extending in a second direction that is different from the first direction, each (of the second light blocking linear patterns) including a protruding portion; a first organic layer between (e.g., arranged between) adjacent second light blocking linear patterns; and a second organic layer covering upper surfaces of the second light blocking linear patterns and having a lower refractive index than the first organic layer.

The light blocking linear patterns may each include a main body and the protruding portion, the main body and the protruding portion each may have a columnar shape, and the protruding portion may be on (e.g., arranged on) a portion of an upper surface of the main body, at least one of the light blocking linear patterns may traverse (cross) the light emitting layer and overlaps the light emitting layer in a plan view, the second organic layer may include a first portion and a second portion, the first portion may have the same width as the main body of the light blocking linear pattern, and may be on (e.g., arranged on) an upper surface of the protruding portion of the light blocking linear pattern, and the second portion may protrude downward from the first portion corresponding to the protruding portion (of a corresponding one of the light blocking linear patterns).

The protruding portion may have a height of equal to or greater than about 1 μm and equal to or less than about 5 μm, and may have a height of equal to or greater than about ¼ and equal to or less than about ¾ of an entire height of the light blocking linear pattern (e.g., a corresponding light blocking linear pattern), and the protruding portion may have a width of equal to or greater than about ¼ and equal to or less than about ¾ of a width of the main body, a height of the main body of the light blocking linear pattern may be equal to or greater than about 4 μm and equal to or less than about 30 μm, and the entire height of the light blocking linear pattern (e.g., see BL of FIG. 4) up to the protruding portion (e.g., see BL-2 of FIG. 4) may be equal to or greater than about 5 μm and equal to or less than about 35 μm, an entire height of the second organic layer up to the second portion may be equal to or greater than about 6 μm and equal to or less than about 10 μm, and a height of the first portion of the second organic layer may be equal to or greater than 0 and equal to or less than about 5 μm, an entire height of the first organic layer may be equal to or greater than about 10 μm and equal to or less than about 40 μm, the width of the main body of the light blocking linear pattern may be equal to or greater than about 1 μm and equal to or less than about 5 μm, and a width of the first organic layer may be equal to or greater than about 4 μm and equal to or less than about 10 μm, and a width of a portion on which the first organic layer may be arranged to a width of a portion on which the first organic layer may not be arranged has a ratio of equal to or greater than 3:1 and equal to or less than 5:1.

In one or more embodiments, the electronic device or the vehicle may further include: a reflective layer between (e.g., arranged between) the light blocking linear pattern and the first organic layer and between the second organic layer and the first organic layer, wherein the reflective layer may have a thickness of equal to or greater than about 200 Å and equal to or less than about 500 Å.

In one or more embodiments, the second organic layer may further include scatterers with a refractive index that is different from a refractive index of the second organic layer, and the scatterers may include at least one of titanium dioxide (TiO₂), silicon dioxide (SiO₂), zirconium oxide (ZrO₂), aluminum oxide (Al₂O₃), hollow silica, an acrylate-based material, or a silicon-based material.

According to one or more embodiments, the light blocking linear patterns may be formed on a front surface in a direction so that light emitted by the light emitting layer is not discharged in a specific direction, and there may be a protruding portion on a portion of the upper surface of the light blocking linear pattern, and the reflective layer may be formed, thereby increasing the light efficiency of the display device.

The light emitted by the display device used in the vehicle may not be provided to a windshield of the vehicle so light reflected on the windshield of the vehicle may not hinder the view of a driver at night.

In one or more embodiments, the light emitted by the display device arranged on a passenger seat is not directed to the driver so driving is not hindered.

When compared to comparative examples that include a film-type (kind) light blocking linear pattern formed on the front surface thereof, the present embodiments may form the light blocking linear patterns in the display device (e.g., the emissive display device), thereby having the merits of eliminating misalignment problems, removing the moiré phenomenon, reducing the thickness, reducing the manufacturing cost, and providing high transmittance.

For example, embodiments of the present disclose provide light blocking linear patterns formed on the front surface of a display device to prevent or reduce light from being emitted in a specific direction, thereby increasing light efficiency. These patterns may include a protruding portion with a reflective layer. In vehicles, this technology prevents light from being reflected on the windshield, avoiding obstruction of the driver's view at night. Additionally, light emitted from a display on the passenger seat is directed away from the driver to avoid hindrance. Compared to film-type light blocking patterns, these embodiments eliminate misalignment issues, remove the moiré phenomenon, reduce thickness and manufacturing costs, and/or provide high transmittance.

### BRIEF DESCRIPTION OF THE DRAWINGS

The accompanying drawing is included to provide a further understanding of the present disclosure and are incorporated in and constitute a part of the present disclosure. The drawing illustrates embodiments of the present disclosure and, together with the description, serve to explain principles of the present disclosure. The above and other aspects, features, and advantages of certain embodiments of the disclosure will be more apparent from the following description taken in conjunction with the accompanying drawings.

FIG. 1 shows a top plan view of a pixel of a light emitting display device according to one or more embodiments of the present disclosure.

FIG. 2 shows a top plan view of light blocking linear patterns and an upper transparent organic layer formed in a light emitting display device according to one or more embodiments of the present disclosure.

FIG. 3 shows a top plan view of a light emitting display device that is a feature combination of FIG. 1 and FIG. 2 according to one or more embodiments of the present disclosure.

FIG. 4 shows a cross-sectional view with respect to the line IV-IV of FIG. 3 according to one or more embodiments of the present disclosure.

FIG. 5 shows a light path according to one or more embodiments of FIG. 4.

FIG. 6 shows a light path according to a comparative example of the present disclosure.

FIGS. 7-12 sequentially show a method for manufacturing a light blocking linear pattern of a light emitting display device according to one or more embodiments of the present disclosure.

FIG. 13 shows a cross-sectional view of a light emitting display device according to one or more embodiments of the present disclosure.

FIG. 14A and FIG. 14B show a case in which a light emitting display device is applied to a vehicle according to a comparative example of the present disclosure.

FIG. 15A and FIG. 15B show a case in which a light emitting display device is applied to a vehicle according to one or more embodiments of the present disclosure.

FIG. 16 shows a case in which a light emitting display device is applied to a vehicle according to one or more embodiments of the present disclosure.

FIG. 17 shows a cross-sectional structure of a light emitting display device according to one or more embodiments of the present disclosure.

### DETAILED DESCRIPTION

The present disclosure will be described more fully hereinafter with reference to the accompanying drawings, in which example embodiments of the disclosure are shown. As those skilled in the art would realize, the described embodiments may be modified in one or more suitably different ways, all without departing from the spirit or scope of the present disclosure.

Parts that are irrelevant to the description will not be provided to clearly describe the present disclosure, and the same or similar elements will be designated by the same reference numerals or reference letters throughout the disclosure.

The size and thickness of each configuration shown in the drawings may be illustratively shown for better understanding and ease of description, but embodiments of the present disclosure are not limited thereto. The thicknesses of layers, films, panels, regions, and/or the like, may be enlarged for clarity. In one or more embodiments, the thicknesses of some layers and areas may be exaggerated for convenience of explanation.

It should be understood that if (e.g., when) an element such as a layer, a film, a region, or a substrate is referred to as being “on” another element, it may be directly on the other element or intervening elements may also be present therebetween. In contrast, if (e.g., when) an element is referred to as being “directly on” another element, there are no intervening elements present therebetween. The word “on” or “above” refers to being positioned on or below the object portion, and does not necessarily refer to being positioned on the upper side of the object portion based on a gravitational direction.

Unless explicitly stated to the contrary, the word “comprise/include,” and variations such as “comprises/includes” and “comprising/including,” should be understood to imply the inclusion of stated elements but not the exclusion of any other elements.

The phrase “in a plan view” refers to viewing an object portion from the top or above, and the phrase “in a cross-sectional view” refers to viewing a cross-section in which the object portion is perpendicularly cut from the side.

When it is stated that a part is “connected” to another part, the part may be “directly connected” to the other part, or may be “connected” to the other part through a third part, or may be connected to the other part physically or electrically, and they may be referred to by different titles or manners depending on positions or functions, but parts that are substantially integrated into one body may be connected to each other.

When parts such as wires, layers, films, regions, plates, and constituent elements are stated to extend in a “first direction” or a “second direction,” this not only signifies a straight-line shape running straight in a corresponding direction, but also includes a structure generally extending in the first direction or the second direction, a structure bent on a set or predetermined part, a zigzag-shaped structure, or a curved structure.

Electronic devices (e.g., mobile phones, televisions (TVs), monitors, laptop computers, and/or the like,) including the display device and the display panel described in the present disclosure or the electronic devices including the display device and the display panel manufactured by a manufacturing method described in the disclosure are not excluded from the range or the scope claimed herein and equivalents thereof.

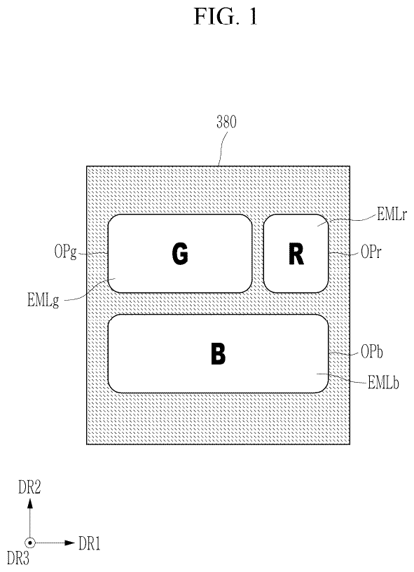

A light blocking linear pattern formed and included in a light emitting display device according to one or more embodiments will now be described with reference to FIG. 1 to FIG. 4.

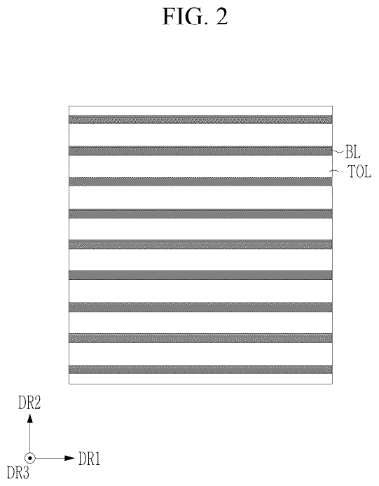

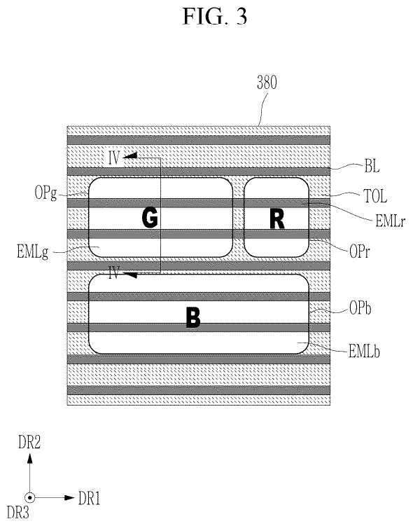

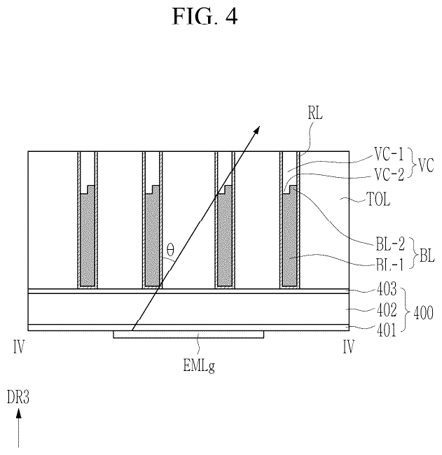

FIG. 1 shows a top plan view of a pixel of a light emitting display device according to one or more embodiments, FIG. 2 shows a top plan view of light blocking linear patterns and an upper transparent organic layer formed in a light emitting display device according to one or more embodiments, FIG. 3 shows a top plan view of a light emitting display device that is a feature combination of FIG. 1 and FIG. 2, and FIG. 4 shows a cross-sectional view with respect to the line IV-IV of FIG. 3.

FIG. 1 shows three light emitting diodes arranged near one another and displaying different colors of R (e.g., red), G (e.g., green), and B (e.g., blue, and the respective light emitting diodes include light emitting layers EMLr, EMLg, and EMLb.

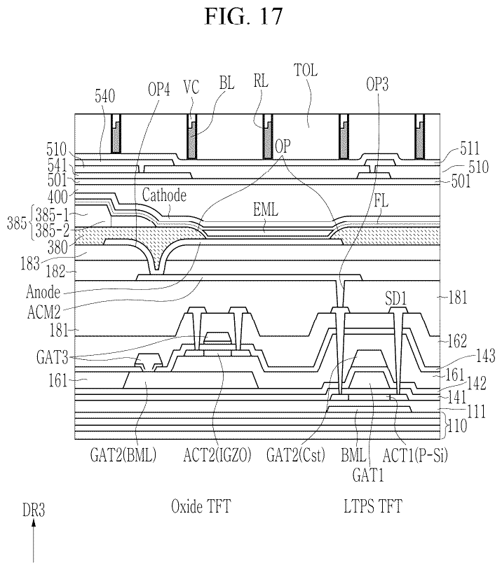

The light emitting layers EMLr, EMLg, and EMLb is to emit light in the light emitting diodes, and are partitioned by a pixel defining layer 380. The light emitting layers EMLr, EMLg, and EMLb may respectively overlap openings OPr, OPg, and OPb arranged in the pixel defining layer 380, and at least a portion of each of the light emitting layers EMLr, EMLg, and EMLb may not overlap the pixel defining layer 380 and may be exposed upward. Depending on embodiments, the light emitting layers EMLr, EMLg, and EMLb may be respectively arranged in the openings OPr, OPg, and OPb of the pixel defining layer 380. In one or more embodiments, a cathode and an encapsulation layer may be arranged on the pixel defining layer 380 and the light emitting layers EMLr, EMLg, and EMLb, and an anode may be arranged below each of the light emitting layers EMLr, EMLg, and EMLb. One anode, one of the light emitting layers EMLr, EMLg, and EMLb, and the cathode may configure one light emitting diode. A detailed stacking structure of the light emitting diode will be described later with reference to FIG. 17.

FIG. 2 shows a planar structure of light blocking linear patterns BL arranged on an upper portion of the light emitting diodes and an upper transparent organic layer TOL (or a first organic layer) arranged around them. Referring to FIG. 4, a reflective layer (see RL of FIG. 4) may be arranged between the light blocking linear pattern BL and the upper transparent organic layer TOL, which is not shown in FIG. 2 for conciseness. Referring to FIG. 4, a low-refractive layer (see VC of FIG. 4) may be arranged on the light blocking linear patterns BL.

The light blocking linear patterns BL may extend in one direction, and gaps between adjacent light blocking linear patterns BL are arranged to be constant. In one or more embodiments, the gaps between the light blocking linear patterns BL may not be constant.

The upper transparent organic layer TOL may be arranged in a region in which the light blocking linear patterns BL are not formed, and light blocking linear patterns BL may be formed in an opening formed in the upper transparent organic layer TOL. The upper transparent organic layer TOL may be arranged in a region in which the light blocking linear pattern BL is not formed, and may not overlap the light blocking linear pattern BL in a plan view. Referring to FIG. 4, the reflective layer (see RL of FIG. 4) may be arranged between the upper transparent organic layer TOL and the light blocking linear pattern BL, and a low-refractive layer (see VC of FIG. 4) may be arranged on the light blocking linear pattern BL.

FIG. 3 shows an embodiment of one of the structures in which the light blocking linear patterns BL and the upper transparent organic layer TOL as shown in FIG. 2 is arranged on the upper portion of the light emitting diode having the arrangement of FIG. 1.

In the embodiment of FIG. 3, one light blocking linear pattern BL traverses one light emitting diode, and at least one light blocking linear pattern BL is arranged on both (e.g., simultaneously) sides (e.g., opposite sides) of the light emitting diodes—that is, between the adjacent light emitting diodes. For example, at least one light blocking linear pattern BL may be arranged between a pair of light emitting diodes. For example, at least one light blocking linear pattern BL may be positioned on both sides of the light emitting diodes, ensuring that the light blocking linear patterns are placed between adjacent light emitting diodes. This arrangement may enhance the control of light emission and blocking, enhancing the overall performance of the device.

For example, in one or more embodiments, the light emitting layers EMLr, EMLg, and EMLb and/or the respective openings OPr, OPg, and OPb of the pixel defining layer 380 each overlap two light blocking linear patterns BL, and the two light blocking linear patterns BL traverse the light emitting layers EMLr, EMLg, and EMLb and/or the openings OPr, OPg, and OPb of the pixel defining layer 380. The two light blocking linear patterns BL do not overlap with each other in each of the light emitting layers EMLr, EMLg, and EMLb and/or the openings OPr, OPg, and OPb of the pixel defining layer 380 but are arranged adjacent, and the two light blocking linear patterns BL overlap the pixel defining layer 380.

The cross-sectional line IV-IV of FIG. 3 is formed with respect to the green-light emitting layer EMLg so the cross-sectional structure of the green-light emitting layer EMLg will now be described in more detail in FIG. 4.

FIG. 4 shows the green-light emitting layer EMLg, and the anode and the cathode that may be arranged above or below the green-light emitting layer EMLg is omitted for clarity. When the light emitting diode emits light, it indicates that the green-light emitting layer EMLg emits light, and the light output by the green-light emitting layer EMLg may be discharged in many directions. However, the light is not transmitted by more than a set or predetermined angle because of the light blocking linear pattern BL arranged on the upper portion of the green-light emitting layer EMLg. As a result, a viewing angle of the display device (i.e., emissive display device) is controlled or selected.

The viewing angle of the emissive display device may be set by a distance between the light blocking linear pattern BL and the green-light emitting layer EMLg, the gap between the adjacent light blocking linear patterns BL, and a width and a height of the light blocking linear patterns BL, and characteristics of the light blocking linear patterns BL according to one or more embodiments will now be described.

The light blocking linear pattern BL may be made of a material for blocking light, and may be made of the same material as a light blocking layer (or a black matrix) used in the emissive display device. The light blocking linear pattern BL may be made of an organic material including a black pigment.

Referring to FIG. 4, the light blocking linear pattern BL may have a columnar shape of which a portion protrudes upward (in a third direction DR3 of FIG. 4), and may be divided into a main body BL-1 and a protruding portion BL-2, each having a columnar shape. Regarding the light blocking linear pattern BL, the protruding portion BL-2 is formed on a portion of an upper surface of the main body BL-1, and an upper surface of the light blocking linear pattern BL has steps. A lateral surface of the protruding portion BL-2 may be arranged in an extension line of a lateral surface of the main body BL-1.

The light blocking linear pattern BL may have a height of equal to or greater than about 5 μm and equal to or less than about 35 μm, and may have a width of equal to or greater than about 1 μm and equal to or less than about 5 μm. A height of the protruding portion BL-2 may be equal to or greater than about 1 μm and equal to or less than about 5 μm, and may have equal to or less than about ⅕ the height of the light blocking linear pattern BL. A width of the protruding portion BL-2 may be half the width of the main body BL-1 of the light blocking linear pattern BL, and depending on embodiments, it may be equal to or greater than about ¼ and equal to or less than about ¾ the width of the main body BL-1.

FIG. 4 shows that the light blocking linear pattern BL has a constant width, and depending on embodiments, the width may vary with height, may be thicker in the middle, or may be thicker at the top or the bottom.

The upper surface of the light blocking linear pattern BL is shown to be planar, and depending on embodiments, the upper surface of the light blocking linear pattern BL may be etched and may have a concave portion or a convex portion during the process.

A low-refractive layer VC (or a second organic layer or a cover layer) may be arranged on the upper surface of the light blocking linear pattern BL in the third direction DR3. The low-refractive layer VC is divided into a first portion VC-1 and a second portion VC-2. The first portion VC-1 has the same width as the light blocking linear pattern BL, and is arranged on the protruding portion BL-2 of the light blocking linear pattern BL in the third direction DR3. The second portion VC-2 protrudes at the first portion VC-1 in a direction opposite to the third direction DR3, corresponding to the protruding portion BL-2 of the light blocking linear pattern BL. The second portion VC-2 may have a width that is equal to the subtraction of the width of the protruding portion BL-2 from the width of the light blocking linear pattern BL.

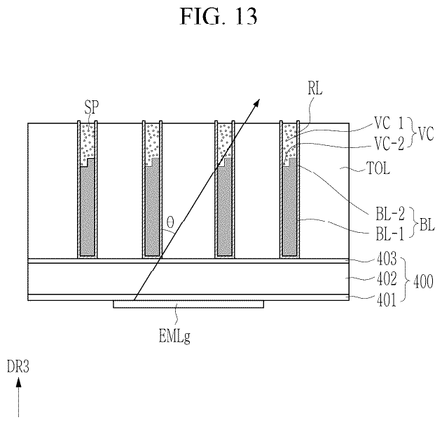

The low-refractive layer VC may be made of an organic material with a relatively lower refractive index than the upper transparent organic layer TOL, and may further include scatterers (see SP of FIG. 13) therein. If (e.g., when) the refractive index of the upper transparent organic layer TOL is about 1.65, the low-refractive layer VC may be made of a transparent organic material with the refractive index of 1.5. For example, in one or embodiments, the low-refractive layer VC may be made of a transparent organic material with a refractive index of equal to or less than 1.5, and depending on embodiments, in one or more embodiments, a low-refractive index of about 1.46 may be used.

A width of the low-refractive layer VC may be equal to the width of the light blocking linear pattern BL, and the low-refractive layer VC may cover the step of the upper surface of the light blocking linear pattern BL. A height from an upper surface of the low-refractive layer VC to the upper surface of the protruding portion BL-2 of the light blocking linear pattern BL may be equal to a difference between a height of the upper transparent organic layer TOL and the height of the light blocking linear pattern BL. Depending on embodiments, in one or more embodiments, the height of the upper transparent organic layer TOL may be equal to the height of the light blocking linear pattern BL, and the low-refractive layer VC may not be arranged on the upper surface of the protruding portion BL-2 of the light blocking linear pattern BL.

The reflective layer RL may be arranged between the light blocking linear pattern BL and the upper transparent organic layer TOL and between the low-refractive layer VC and the upper transparent organic layer TOL. In more detail, a lateral surface of the light blocking linear pattern BL and a lateral surface of the low-refractive layer VC contacts the reflective layer RL, and according to the embodiment of FIG. 4, a bottom surface of the light blocking linear pattern BL contacts the reflective layer RL. Depending on embodiments, in one or more embodiments, the reflective layer RL contacting the bottom surface of the light blocking linear pattern BL may not be formed or provided.

The reflective layer RL may be formed by a chemical vapor deposition (CVD) method, and may be made of an inorganic insulating material such as silicon oxide (SiOₓ), silicon nitride (SiNₓ), or silicon oxynitride (SiOₓN_{y}). Depending on embodiments, in one or more embodiments, the reflective layer RL may be made of one or more suitable materials for increasing reflectance, and may be made of a thin metal material. In one or more embodiments, the reflective layer RL may have a thickness of equal to or greater than about 200 Å and equal to or less than about 500 Å.

Here, the reflective layer RL may allow the light discharged by the green-light emitting layer EMLg to be reflected from the reflective layer RL without being absorbed and dissipated as it is incident to the light blocking linear pattern BL, thereby increasing efficiency of light.

Depending on embodiments, in one or more embodiments, the reflective layer RL may be formed higher than the upper surface of the low-refractive layer VC, and the reflective layer RL may be formed higher than the upper surface of the upper transparent organic layer TOL and may protrude therefrom (see FIG. 13).

The upper transparent organic layer TOL is arranged in the region in which the light blocking linear pattern BL, the low-refractive layer VC, and the reflective layer RL are not arranged.

The upper transparent organic layer TOL may be formed by using a transparent organic material, and the transparent organic material may be a low-temperature transparent organic layer that does not use a high-temperature process when forming the upper transparent organic layer TOL. The transparent organic material may be made of one or more suitable types (kinds) of materials, including an organic material with a higher refractive index than the low-refractive layer VC. The upper transparent organic layer TOL may be made of an organic material with the refractive index of greater than 1.5.

The height of the upper transparent organic layer TOL may correspond to the heights of the light blocking linear pattern BL and the low-refractive layer VC, it may have a height of equal to or greater than about 10 μm and equal to or less than about 40 μm, and it may have a width of equal to or greater than about 4 μm and equal to or less than about 10 μm. A width of the upper transparent organic layer TOL and a width of the region in which the upper transparent organic layer TOL are not arranged—that is, the width of the light blocking linear pattern BL, the low-refractive layer VC, and the reflective layer RL may have the ratio of 4:1, and depending on embodiments, the widths may have the ratio of 3:1 to 5:1.

Depending on embodiments, the height of the upper transparent organic layer TOL and the height of the light blocking linear pattern BL may be determined first, and then the height of the low-refractive index layer (VC) may be formed to fill the remaining height with the low-refractive index layer.

FIG. 4 shows that an encapsulation layer 400 is arranged below the upper transparent organic layer TOL and the light blocking linear pattern BL, and the encapsulation layer 400 may include a lower inorganic encapsulation layer 401, an organic encapsulation layer 402, and an upper inorganic encapsulation layer 403.

The light emitting diode is arranged below the encapsulation layer 400, and FIG. 4 shows the green-light emitting layer EMLg. A detailed structure of the light emitting diode will be described with reference to FIG. 17.

Depending on embodiments, in one or more embodiments, a sensing insulating layer and sensing electrodes may be arranged between the upper transparent organic layer TOL and the encapsulation layer 400 to sense touch. The structure for sensing touch will be described later with reference to FIG. 17.

Referring to FIG. 4, the light blocking linear pattern BL blocks the light emitted by the green-light emitting layer EMLg from being emitted by equal to or greater than a set or predetermined angle (θ; or a viewing angle) with respect to a normal line, and for this purpose, the light blocking linear pattern BL may have a relatively great height. The gap between the adjacent light blocking linear patterns BL may be determined based on an angle at which the light is provided. and depending on embodiments, in one or more embodiments, the gap between the adjacent light blocking linear patterns BL may be less than the height of the light blocking linear pattern BL. If (e.g., when) the gap between the adjacent light blocking linear patterns BL is reduced, the blocked viewing angle (θ) is reduced, which increases the blocking effect but reduces transmittance. Therefore, the transmittance and the blocked viewing angle (θ) are needed to be considered together, and in one or more embodiments, the transmittance may be set as 80%, and the blocked viewing angle (θ) may be set as 30 degrees. In one or more embodiments in which the transmittance may be further reduced, the blocked viewing angle (θ) may be reduced to 15 degrees. In one or more embodiments in which high transmittance is desired or required or in which the blocked viewing angle (θ) may be greater than 30 degrees, in one or more embodiments, the light may be set to prevent or reduce the light from proceeding at one or more suitable angles, and the blocked viewing angle (θ) may be set to an angle of about 45 degrees.

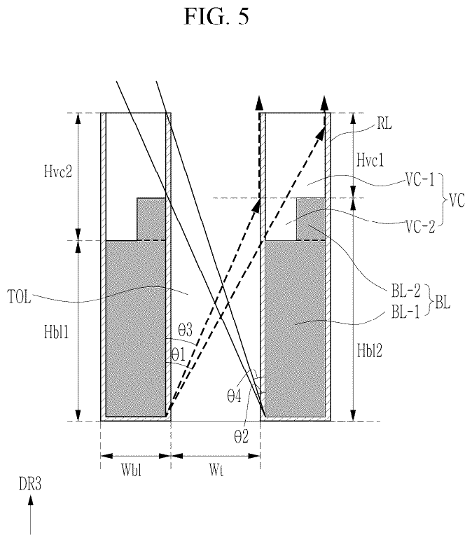

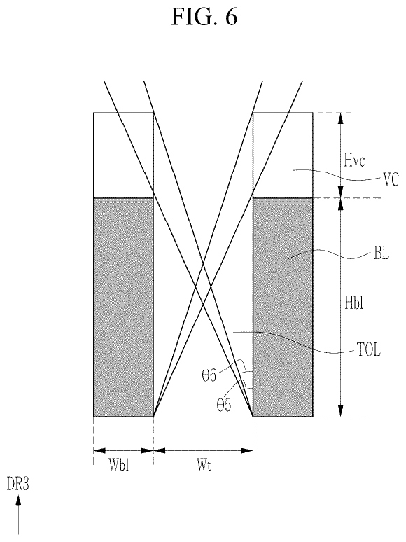

The embodiments of the present disclosure in which the light blocking linear pattern BL is formed in the emissive display device are different from the comparative examples in which the viewing angle is reduced by attaching a film on a front surface of the emissive display device, which will now be described with reference to FIG. 5 and FIG. 6.

FIG. 5 shows a light path according to one or more embodiments of FIG. 4, and FIG. 6 shows a light path according to a comparative example.

Numerical ranges and optical characteristics of respective portions according to one or more embodiments of FIG. 4 will now be described with reference to FIG. 5.

The numerical ranges of the respective portions shown in FIG. 5 will now be described.

A height Hbl1 of the main body BL-1 of the light blocking linear pattern BL may be equal to or greater than about 4 μm and equal to or less than about 30 μm, the height of the light blocking linear pattern BL up to the protruding portion BL-2—that is, an entire height Hbl2—may be equal to or greater than about 5 μm and equal to or less than about 35 μm, and the height of the protruding portion BL-2 may be equal to or greater than about ¼ and equal to or less than about ¾ the height of the light blocking linear pattern BL.

The height of the low-refractive layer VC up to the second portion VC-2—that is, an entire height Hvc2—may be equal to or greater than about 6 μm and equal to or less than about 10 μm, and a height Hvc1 of the first portion VC-1 of the low-refractive layer VC may be equal to or greater than 0 and equal to or less than about 5 μm.

The entire height of the upper transparent organic layer TOL may be equal to or greater than about 10 μm and equal to or less than about 40 μm.

A width Wbl of the light blocking linear pattern BL may be equal to or greater than about 1 μm and equal to or less than about 5 μm, and a width Wt of the upper transparent organic layer TOL may be equal to or greater than about 4 μm and equal to or less than about 10 μm. The width of the portion in which the upper transparent organic layer TOL is arranged and the width of the portion in which the upper transparent organic layer TOL is not arranged—that is, the portion in which the light blocking linear pattern BL, the low-refractive layer VC, and the reflective layer RL are arranged—may have the ratio of 4:1, and depending on embodiments, the widths may have the ratio of 3:1 to 5:1.

The optical characteristic of the structure of FIG. 4 will now be described.

The light blocking linear pattern BL is made of a light blocking material, so if (e.g., when) the light emitted by the light emitting layer is input to the light blocking linear pattern BL, it may be absorbed and dissipated. To increase light efficiency, the reflective layer RL may be formed around the light blocking linear pattern BL so that at least part of the light proceeding toward the light blocking linear pattern BL may not be input to the light blocking linear pattern BL.

Among the light emitted by the light emitting layer, light that does not proceed toward the light blocking linear pattern BL and light that proceeds toward the low-refractive layer VC may proceed to the front surface as light is refracted by a refractive index, and some of the light may be totally reflected as marked as light of θ1 and/or 03 in FIG. 5. For the purpose of the characteristic of total reflection, the refractive index of the low-refractive layer VC may have a lower refractive index than the upper transparent organic layer TOL. The reflective layer RL is arranged between the upper transparent organic layer TOL and the low-refractive layer VC, so some light may be reflected. Depending on embodiments, in one or more embodiments, the reflective layer RL may not be formed between the upper transparent organic layer TOL and the low-refractive layer VC.

A path of light shown in FIG. 5 will now be described in more detail, and each angle is measured with respect to a normal line.

The light proceeding at the angle θ1 proceeds at the angle connecting an upper corner of the main body BL-1 of the light blocking linear pattern BL and a lower corner of the main body BL-1 of the adjacent light blocking linear pattern BL. The light proceeding at the angle that is greater than θ1 may be absorbed into or reflected on the main body BL-1 of the light blocking linear pattern BL and may proceed with another angle, so images may not be seen at a viewing angle that is greater than θ1. The light proceeding at the angle of θ1 may not meet the protruding portion BL-2 of the light blocking linear pattern BL. Therefore, the angle of θ1 may correspond to the viewing angle in one direction of the corresponding emissive display device. If (e.g., when) the light proceeding at the angle of θ1 is absorbed by the protruding portion BL-2 of the light blocking linear pattern BL, it may have the angle that is less than θ1 as the viewing angle. If (e.g., when) the light proceeding at the angle of θ1 passes through the low-refractive layer VC arranged on an upper portion of the light blocking linear pattern BL and meets the reflective layer RL and/or the upper transparent organic layer TOL, it may be totally reflected as shown in FIG. 5.

The light blocking linear pattern BL may have different viewing angles with respect to the direction because of the protruding portion BL-2, and the viewing angle in another direction may be θ2. In more detail, the light proceeding at the angle of θ2 proceeds at the angle connecting an upper corner of the protruding portion BL-2 of the light blocking linear pattern BL and a lower corner of the main body BL-1 of the adjacent light blocking linear pattern BL. The light proceeding at the angle that is greater than θ2 may be absorbed into or reflected on the light blocking linear pattern BL and may proceed with another angle, so images may not be seen at the viewing angle that is greater than θ2. Therefore, the angle of θ2 may correspond to the viewing angle of the corresponding light emitting display device in another direction.

The light proceeding at the angle of θ3 proceeds in substantially the same one side as the light proceeding at the angle of θ1 and proceeds with the angle that is less than θ1 so it is not blocked by the light blocking linear pattern BL. The light proceeding at the angle of θ3 enters the reflective layer RL and the low-refractive layer VC, and is totally reflected on the boundary of the reflective layer RL and/or the low-refractive layer VC because of the refractive index and the incident angle. The light proceeding at the angle of θ3 may be totally reflected if (e.g., when) proceeding to another side in a like way of the light proceeding at the angle of θ2. Therefore, the light proceeding in any directions or with the angle of less than θ3 may be totally reflected on the boundary of the reflective layer RL and/or the low-refractive layer VC. Because of the characteristic of total reflection, light luminance at the front surface has the advantage of increasing, and light efficiency at the front surface also increases.

The light proceeding at the angle of θ4 proceeds to the same other side as the light proceeding at the angle of θ2, and passes through a lower corner of the main body BL-1 of the light blocking linear pattern BL and an upper corner of the reflective layer RL and/or the low-refractive layer VC. As a result, the light proceeding at the angle of equal to or less than 04 may proceed regardless of the light blocking linear pattern BL, the reflective layer RL, and the low-refractive layer VC. The light proceeding at the angle of θ4 may proceed regardless of the light blocking linear pattern BL, the reflective layer RL, and the low-refractive layer VC if (e.g., when) proceeding to one side in a like way of the light proceeding at the angle of θ1.

A comparative example will now be described with reference to FIG. 6.

According to the comparative example of FIG. 6, a light blocking linear pattern BL and a low-refractive layer VC do not have a protruding structure, so their heights are constant and they include no reflective layer RL. For comparison, a width Wbl of the light blocking linear pattern BL and a width Wt of the upper transparent organic layer TOL will be set to correspond to the embodiment of FIG. 5, and a height Hbl of the light blocking linear pattern BL and a height Hvc of the low-refractive layer VC will be set to correspond to the height Hbl1 of the main body BL-1 of the light blocking linear pattern BL and the height Hvc1 of the first portion VC-1 of the low-refractive layer VC according to the embodiment of FIG. 5.

The light proceeding at the angle of θ5 in FIG. 6 proceeds at the angle connecting an upper corner of the light blocking linear pattern BL and a lower corner of the adjacent light blocking linear pattern BL, and the angle may be equal to the angle of θ1 of FIG. 5.

The light proceeding at the angle of θ6 in FIG. 6 passes through a lower corner of the light blocking linear pattern BL and a corner of the low-refractive layer VC, and the angle may be equal to the angle of θ4 of FIG. 5.

Unlike the embodiment of FIG. 5, the optical characteristics of the comparative example like FIG. 6 are that there is no reflective layer RL and the light input to the light blocking linear pattern BL is absorbed into the light blocking linear pattern BL so the light fails to reach the front surface, thereby degrading light efficiency, and the angle by which total reflection is generated is also formed to be relatively less. As a result, the comparative example has the disadvantage that light efficiency and front surface luminance are lower than in the embodiment of FIG. 5.

In comparison to the comparative example of attaching the film, the embodiment of FIG. 5 attaches no film, so no misalignment problem may be generated, and the moiré phenomenon due to erroneous attachment may be reduced or eliminated. In addition, the comparative example of attaching the film has the disadvantage of increasing the manufacturing cost and reducing transmittance because of the loss of light generated on the interface by an adhesive during attachment. For example, in contrast to the comparative example where a film is attached, the embodiment shown in FIG. 5 does not use a film. This eliminates potential misalignment issues and reduces or eliminates the moiré phenomenon caused by incorrect attachment. Additionally, the comparative example with the film has drawbacks such as increased manufacturing costs and reduced transmittance due to light loss at the adhesive interface during attachment.

Referring to FIG. 3 and FIG. 4, some of the light blocking linear patterns BL overlap the light emitting diode or the light emitting layers EMLr, EMLg, and EMLb, and the rest thereof overlap the pixel defining layer 380. In the embodiments of FIG. 3 and FIG. 4, each of the light emitting layers EMLr, EMLg, and EMLb overlap the two light blocking linear patterns BL, and the number and positions of the overlapping light blocking linear patterns BL may be variable.

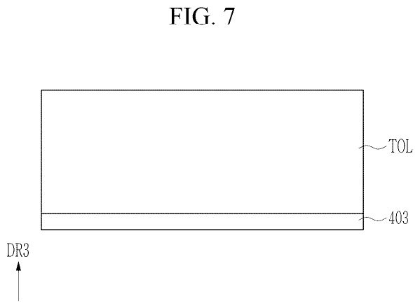

A method for manufacturing a light blocking linear pattern according to one or more embodiments will now be described with reference to FIG. 7 to FIG. 12.

FIG. 7 to FIG. 12 sequentially show a method for manufacturing a light blocking linear pattern of a light emitting display device according to one or more embodiments.

FIG. 7 to FIG. 12 show that constituent layers of the light blocking linear patter are manufactured, and show the upper inorganic encapsulation layer 403 included in the encapsulation layer 400.

Referring to FIG. 7, an upper transparent organic layer TOL is formed on the upper inorganic encapsulation layer 403.

The upper transparent organic layer TOL may be made of a transparent organic material and may be made of a transparent organic material with a higher refractive index than an low-refractive layer VC to be formed, and one or more suitable types (kinds) of transparent organic material with the refractive index of greater than 1.5 may be used. The upper transparent organic layer TOL may be a low-temperature transparent organic layer using no high-temperature process in the case of stacking. The material for the upper transparent organic layer TOL may be stacked till a thickness that corresponds to the height of the light blocking linear pattern BL to be formed, and may be stacked to have the thickness of equal to or greater than about 10 μm and equal to or less than about 40 μm.

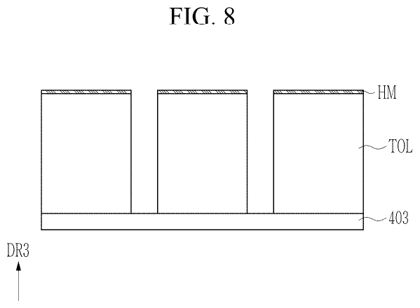

As shown in FIG. 8, a patterned hard mask HM is formed on the upper transparent organic layer TOL, and the upper transparent organic layer TOL is dry-etched by using the pattern of the hard mask HM as a mask to thus form an opening. The upper transparent organic layer TOL exposed by the pattern of the hard mask HM may be etched, and the upper inorganic encapsulation layer 403 may be exposed. The hard mask HM may be made of a metal such as aluminum (Al) or molybdenum (Mo), or alloys thereof. The opening formed in the upper transparent organic layer TOL extends in one direction.

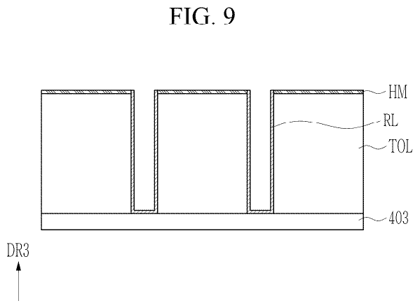

As shown in FIG. 9, a reflective layer RL is formed in the opening formed in the upper transparent organic layer TOL by a chemical vapor deposition (CVD) method. The reflective layer RL may be arranged on an upper surface of the pattern of the hard mask HM. The reflective layer RL may be formed to have a thickness of equal to or greater than about 200 Å and equal to or less than about 500 Å.

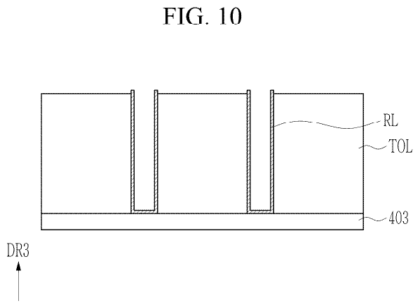

As shown in FIG. 10, the pattern of the hard mask HM is then removed. The reflective layer RL arranged on the upper surface of the pattern of the hard mask HM may also be removed. Referring to FIG. 10, the reflective layer RL may be arranged in the opening of the upper transparent organic layer TOL and may partly protrude to an upper portion of the upper transparent organic layer TOL.

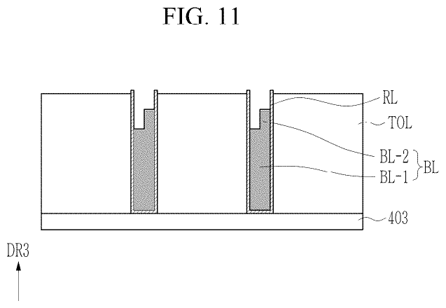

As shown in FIG. 11, the light blocking linear pattern BL is formed in the opening of the upper transparent organic layer TOL and is made of an organic material including a black pigment on the reflective layer RL. The organic material forming the light blocking linear pattern BL may be a material (or photoresist) for generating a chemical change if (e.g., when) beams are irradiated. The black pigment may include a light blocking material, and the light blocking material may include a resin or a paste including carbon black, carbon nanotubes, and black dyes, metal particles—for example, nickel, aluminum, molybdenum, and alloys thereof—and/or metal oxide particles (e.g., chromium nitride). The organic material forming the light blocking linear pattern BL may include a light blocking material to have the black color, and may have the characteristic of not reflecting light but absorbing/blocking it.

The light blocking linear pattern BL may provide different exposed amounts to the organic material including a black pigment depending on its position, or a halftone mask with a different exposed amount is used, exposed, and developed to form the light blocking linear pattern BL including the protruding portion BL-2.

Referring to FIG. 11, the light blocking linear pattern BL does not fill the entire opening of the upper transparent organic layer TOL.

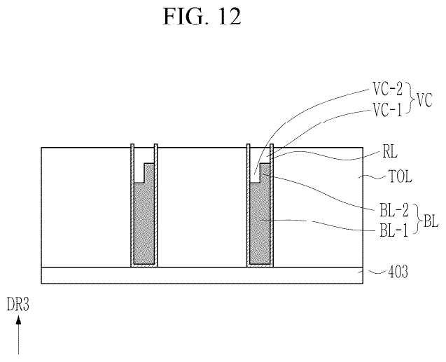

Referring to FIG. 12, a low-refractive layer VC is formed in the opening of the upper transparent organic layer TOL and on an upper portion of the light blocking linear pattern BL. The low-refractive layer VC may be made of a transparent organic material with a relatively lower refractive index than the upper transparent organic layer TOL, and may fill the rest of the opening of the upper transparent organic layer TOL.

Depending on embodiments, in one or more embodiments, a dry ashing process may be performed on the entire region to planarize the upper surface and remove the protruding reflective layer RL. However, depending on embodiments, in one or more embodiments, the protruding reflective layer RL may not be removed, and the structure including a protruding reflective layer RL will now be described with reference to FIG. 13.

FIG. 13 shows a cross-sectional view of a light emitting display device according to one or more embodiments of the present disclosure.

Unlike the embodiments of FIG. 3 and FIG. 4, the embodiments of FIG. 13 have the structure in which the reflective layer RL is formed higher than the upper surface of the upper transparent organic layer TOL to thus protrude, and the low-refractive layer VC may additionally include scatterers SP. The scatterers SP may be made of a material with a different refractive index from the low-refractive layer VC, and for example, they may include at least one of titanium dioxide (TiO₂), silicon dioxide (SiO₂), zirconium oxide (ZrO₂), aluminum oxide (Al₂O₃), hollow silica, an acrylate-based material, or a silicon-based material. Regarding the hollow silica, the inside of the particles of silicon oxide (SiO₂) having a three-dimensional shape such as a sphere may be empty.

The embodiments of FIG. 13 may have optical characteristics similar to the embodiment of FIG. 3 and FIG. 4, but they may have following optical differences.

A portion of the reflective layer RL, formed higher than the upper surface of the upper transparent organic layer TOL, represents an extended portion of the totally reflected portion so that the light proceeding to the front surface may further increase and luminance of the front surface may increase.

The scatterers SP may change the angle of light passing through the low-refractive layer VC, may scatter the light proceeding to a lateral surface, and may increase the light proceeding to the front surface, thereby increasing the luminance of the front surface.

The embodiments of FIG. 13 has the same optical characteristics in that the light efficiency increases as described in FIG. 3 and FIG. 4, and the light of equal to or greater than a set or predetermined angle is blocked.

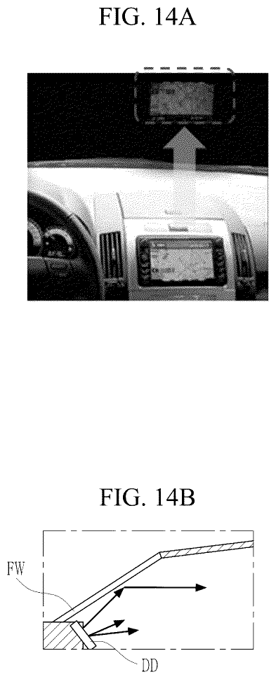

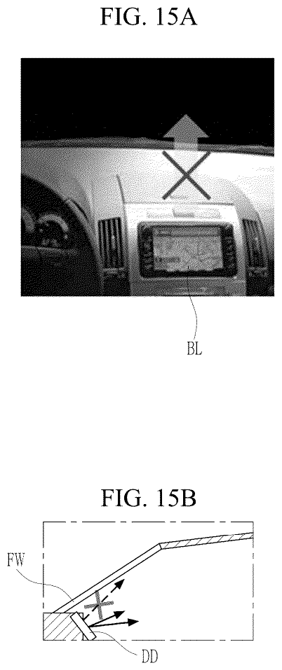

An effect given if (e.g., when) the light emitting display device including the light blocking linear pattern BL is applied to a vehicle will be compared with the comparative example of FIGS. 14A-14B and will now be described with reference to FIGS. 15A-15B.

FIGS. 14A-14B shows a case in which a light emitting display device according to a comparative example is applied to a vehicle, and FIGS. 15A-15B shows a case in which a light emitting display device according to one or more embodiments of the present disclosure is applied to a vehicle.

According to a comparative example of FIGS. 14A-14B, a light emitting display device DD (see FIG. 14B) used in a vehicle includes no light blocking linear pattern BL, so as shown in FIG. 14B, the angle of the emitted light is not limited and the light is discharged in many directions.

In contrast, in the embodiment of FIGS. 15A-15B, a light emitting display device DD used in a vehicle includes light blocking linear patterns BL arranged in one direction (or a horizontal direction) and partly blocks the light discharged in an upper direction and a lower direction. The light with greater than a set or predetermined angle may be blocked with respect to the normal line that is perpendicular to the front surface of the light emitting display device DD.

Referring to FIG. 14B, the light emitted by the light emitting display device DD arranged on a center fascia portion of the vehicle may be provided to a windshield FW of the vehicle, and the light emitted from the light emitting display device DD may be reflected on the windshield FW and may be provided to the eyes of a driver at night, thereby hindering the view of the driver.

In contrast, referring to FIGS. 15A-15B, the light blocking linear patterns BL are included in the light emitting display device DD used in the vehicle so that the light emitted by the light emitting display device DD may not be transmitted to a windshield FW of the vehicle, may not be reflected on the windshield FW at night, and thus may not hinder the view of a driver.

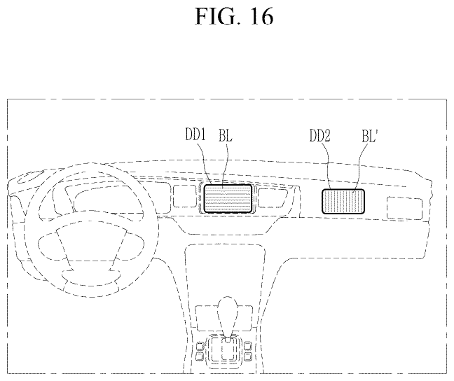

Depending on embodiments, arranged directions of the light emitting display device DD used in the vehicle and the light blocking linear patterns BL may be variable, of which one or more embodiments will now be described with reference to FIG. 16.

FIG. 16 shows a case in which a light emitting display device according to the one or more embodiments is applied to a vehicle.

Two light emitting display devices DD1 and DD2 are attached to the vehicle according to one or more embodiments of FIG. 16.

As shown in FIG. 16, a first light emitting display device DD1 is arranged on a center fascia of the vehicle and has light blocking linear patterns BL arranged in a horizontal direction. As a result, light is not reflected on a windshield of the vehicle and the view of a driver is not interrupted.

a second light emitting display device DD2 is arranged in front of a passenger seat of the vehicle, and has light blocking linear patterns BL′ arranged in a perpendicular direction. The light emitted by the second light emitting display device DD2 is not provided in the right and left directions because of the light blocking linear patterns BL′ arranged in the perpendicular direction so that a person sitting in the passenger seat may see the screen of the second light emitting display device DD2, and the driver may not see the screen of the second light emitting display device DD2. This has the advantage of allowing the driver to focus on driving and not being distracted by the second light emitting display device DD2 when driving the vehicle.

The schematic structure of the light emitting display device, the light blocking linear pattern BL, the peripheral structure thereof, and the manufacturing method thereof have been described in more detail.

A structure of the light emitting diode arranged on a lower portion of the light blocking linear pattern BL will now be described with reference to FIG. 17.

FIG. 17 shows a cross-sectional structure of a light emitting display device according to one or more embodiments of the present disclosure.

FIG. 17 shows a stacking structure of one of pixels arranged in a display area of the light emitting display device.

The light emitting display device may be divided into a lower panel layer and an upper panel layer, and a light emitting diode and a pixel circuit configuring the pixel are arranged on the lower panel layer, and the lower panel layer may include an encapsulation layer 400 for covering them. The pixel circuit may include a second organic layer 182 and a third organic layer 183 and may represent a lower configuration thereof, and the light emitting diode may be on an upper portion of the third organic layer 183 and may represent a configuration arranged on a lower portion of the encapsulation layer 400. The structure arranged on an upper portion of the encapsulation layer 400 may correspond to the upper panel layer, and the light blocking linear patterns BL may be included in the upper panel layer. Depending on embodiments, in one or more embodiments, the third organic layer 183 may not be included.

Referring to FIG. 17, a metal layer BML is arranged on a substrate 110.

The substrate 110 may include a material that does not bend due to rigid characteristics such as glass, or may include a flexible material that may bend such as a plastic or a polyimide. As shown in FIG. 17, the flexible substrate may have a structure in which a two-layered structure of a barrier layer made of a polyimide and an inorganic insulating material arranged thereon may have a double structure.

The metal layer BML may be formed on a position at which the metal layer BML overlaps a channel of a driving transistor selected from among a first semiconductor layer ACT (P—Si) in a plan view, and is also referred to as a lower shielding layer. The metal layer BML may include a metal such as copper (Cu), molybdenum (Mo), aluminum (Al), or titanium (Ti), or any metal alloy thereof. The driving transistor may generate a current transmitted to the light emitting diode.

A buffer layer 111 for covering the substrate 110 and the metal layer BML is arranged on the substrate 110 and the metal layer BML. The buffer layer 111 may block permeation of impurities into the first semiconductor layer ACT (P—Si), and may be an inorganic insulating layer including silicon oxide (SiOₓ), silicon nitride (SiNₓ), and/or silicon oxynitride (SiOₓN_{y}).

The first semiconductor layer ACT1 (P—Si) made of a silicon semiconductor (e.g., polycrystalline semiconductor (P—Si)) is arranged on the buffer layer 111. The first semiconductor layer ACT1 (P—Si) includes a channel of a polycrystalline transistor (LTPS TFT) including a driving transistor, and a first region and a second region arranged on the respective sides of the channel of the polycrystalline transistor. The polycrystalline transistor (LTPS TFT) may include one or more suitable types (kinds) of switching transistors in addition to the driving transistor. Both sides of the channel of the first semiconductor layer ACT1 (P—Si) may each have a region that has the characteristic of a conductive layer according to a plasma treatment or doping, and may function as a first electrode and a second electrode of the polycrystalline transistor.

A first gate insulating layer 141 may be arranged on the first semiconductor layer ACT1 (P—Si). The first gate insulating layer 141 may be an inorganic insulating layer including silicon oxide (SiOₓ), silicon nitride (SiNₓ), and/or silicon oxynitride (SiOₓN_{y}).

A first gate conductive layer including a gate electrode GAT1 of the polycrystalline transistor LTPS TFT may be arranged on the first gate insulating layer 141. A scan line or a light emission control line may be formed on the first gate conductive layer in addition to the gate electrode GAT1 of the polycrystalline transistor LTPS TFT. The first gate conductive layer may include a metal such as copper (Cu), molybdenum (Mo), aluminum (Al), or titanium (Ti), or any metal alloy thereof, and may be a single layer or a multilayer.

When the first gate conductive layer is formed, an exposed region of the first semiconductor layer may be made a conductor by performing a plasma treatment or a doping process. For example, the first semiconductor layer ACT1 (P—Si) covered by the first gate conductive layer may not be made a conductor, and a portion of the first semiconductor layer ACT1 (P—Si) not covered by the first gate conductive layer may have the same characteristic as a conductive layer.

A second gate insulating layer 142 may be arranged on the first gate conductive layer and the first gate insulating layer 141. The second gate insulating layer 142 may be an inorganic insulating layer including silicon oxide (SiOₓ), silicon nitride (SiNₓ), and/or silicon oxynitride (SiOₓN_{y}).

A second gate conductive layer GAT2 including one electrode GAT2(Cst) of the storage capacitor Cst and a lower shielding layer GAT2(BML) of an oxide transistor Oxide TFT may be arranged on the second gate insulating layer 142. The lower shielding layer GAT2(BML) of the oxide transistor Oxide TFT may be arranged on a lower portion of a channel of the oxide transistor Oxide TFT and may shield the channel from light or electromagnetic interference provided to the channel from a lower side of the oxide transistor Oxide TFT. The electrode GAT2(Cst) of the storage capacitor Cst may overlap the gate electrode GAT1 of the driving transistor to form the storage capacitor Cst. Depending on embodiments, in one or more embodiments, the second gate conductive layer GAT2 may further include a scan line, a control line, and/or a voltage line. The second gate conductive layer GAT2 may include a metal such as copper (Cu), molybdenum (Mo), aluminum (Al), or titanium (Ti), or any metal alloy thereof, and may be a single layer or a multilayer.

A first interlayer insulating layer 161 may be arranged on the second gate conductive layer GAT2. The first interlayer insulating layer 161 may include an inorganic insulating layer including silicon oxide (SiOₓ), silicon nitride (SiNₓ), or silicon oxynitride (SiOₓN_{y}), and depending on embodiments, in one or more embodiments, the inorganic insulating layer may be made thick.

An oxide semiconductor layer ACT2 (IGZO) (or a second semiconductor layer) including the channel, a first region, and a second region of the oxide transistor Oxide TFT may be arranged on the first interlayer insulating layer 161.

A third gate insulating layer 143 may be arranged on the oxide semiconductor layer ACT2 (IGZO). The third gate insulating layer 143 may be arranged on front surfaces of the oxide semiconductor layer ACT2 (IGZO) and the first interlayer insulating layer 161. The third gate insulating layer 143 may include an inorganic insulating layer including silicon oxide (SiOₓ), silicon nitride (SiNₓ), and/or silicon oxynitride (SiOₓN_{y}).

A third gate conductive layer including a gate electrode GAT3 of the oxide transistor Oxide TFT may be arranged on the third gate insulating layer 143. The gate electrode GAT3 of the oxide transistor Oxide TFT may overlap the channel of the oxide transistor Oxide TFT. The third gate conductive layer may further include a scan line and/or a control line. The third gate conductive layer may include a metal such as copper (Cu), molybdenum (Mo), aluminum (Al), or titanium (Ti), or any metal alloy thereof, and may be a single layer or a multilayer.

A second interlayer insulating layer 162 may be arranged on the third gate conductive layer. The second interlayer insulating layer 162 may be a single layer or a multilayer. The second interlayer insulating layer 162 may include an inorganic insulating material such as silicon nitride (SiNₓ), silicon oxide (SiOₓ), and/or silicon oxynitride (SiOₓN_{y}), and depending on embodiments, in one or more embodiments, it may include an organic material.

A first data conductive layer SD1 including connecting electrodes connected to the first region and the second region of each of the polycrystalline transistor LTPS TFT and the oxide transistor Oxide TFT may be arranged on the second interlayer insulating layer 162. The first data conductive layer SD1 may include a metal such as aluminum (Al), copper (Cu), molybdenum (Mo), or titanium (Ti), or any metal alloy thereof, and may be a single layer or a multilayer.

A first organic layer 181 may be arranged on the first data conductive layer SD1. The first organic layer 181 may be an organic insulator including an organic material, and the organic material may include at least one of a polyimide, a polyamide, an acryl-based resin, a benzocyclobutene-based resin, or a phenol-based resin.

A second data conductive layer including an anode connecting electrode ACM2 may be arranged on the first organic layer 181. The second data conductive layer may include a data line and/or a driving voltage line. The second data conductive layer may include a metal such as aluminum (Al), copper (Cu), molybdenum (Mo), or titanium (Ti), or any metal alloy thereof, and may be a single layer or a multilayer. The anode connecting electrode ACM2 may be connected to the first data conductive layer SD1 through an opening OP3 arranged in the first organic layer 181.

A second organic layer 182 and a third organic layer 183 are each arranged on the second data conductive layer, and an anode connecting opening OP4 is formed on the second organic layer 182 and the third organic layer 183. The anode connecting electrode ACM2 is electrically connected to an anode through the anode connecting opening OP4. The second organic layer 182 and the third organic layer 183 may each be an organic insulator, and may each include at least one of a polyimide, a polyamide, an acryl-based resin, a benzocyclobutene-based resin, or a phenol-based resin. Depending on embodiments, in one or more embodiments, the third organic layer 183 may not be provided.

A pixel defining layer 380 having an opening OP for exposing the anode and covering at least a portion of the anode may be arranged on the anode. The pixel defining layer 380 may be a black pixel defining layer made of a black organic material that prevents light applied from the outside from being reflected back to the outside, and depending on embodiments, in one or more embodiments, it may be made of a transparent organic material. Therefore, depending on embodiments, in one or more embodiments, the pixel defining layer 380 may include a negative-type (kind) black organic material, and may include a black pigment.

A spacer 385 is arranged on the pixel defining layer 380. The spacer 385 may, differing from the pixel defining layer 380, be made of a transparent organic insulating material. According to one or more embodiments, the spacer 385 may be made of a positive-type (kind) transparent organic material. The spacer 385 may include two portions 385-1 and 385-2 with different heights, and the higher portion 385-1 functions as the spacer, and the lower portion 385-2 may increase an adhering characteristic between the spacer and the pixel defining layer 380.

A functional layer FL and a cathode may be sequentially formed on the anode, the spacer 385, and the pixel defining layer 380, and the functional layer FL and the cathode may be arranged in the entire region of the light emitting display device. A light emitting layer EML may be arranged between the functional layer FL, and may be arranged in the opening OP of the pixel defining layer 380. A combination of the functional layer FL and the light emitting layer EML will be referred to as an intermediate layer. The functional layer FL may include at least one selected from among auxiliary layers including an electron injection layer, an electron transport layer, a hole transport layer, and a hole injection layer, and the hole injection layer and the hole transport layer may be arranged on a lower portion of the light emitting layer EML, and the electron transport layer and the electron injection layer may be arranged on an upper portion of the light emitting layer EML.

An encapsulation layer 400 is arranged on the cathode. The encapsulation layer 400 may include at least one inorganic layer and at least one organic layer, and may have a triple-layer structure including a first inorganic encapsulation layer, an organic encapsulation layer, and a second inorganic encapsulation layer in a like way of the embodiment of FIG. 4. The encapsulation layer 400 may protect the light emitting layer EML from moisture and/or oxygen that may be introduced from the outside. According to one or more embodiments, the encapsulation layer 400 may include a structure in which the inorganic layer and the organic layer are sequentially further stacked.

Sensing insulating layers 501, 510, and 511 and sensing electrodes 540 and 541 for sensing touch are arranged on the encapsulation layer 400. In the embodiments of FIG. 17, touch may be sensed in a capacitive type (kind) by using the two sensing electrodes 540 and 541.

In more detail, a first sensing insulating layer 501 is formed on the encapsulation layer 400, and the sensing electrodes 540 and 541 are formed thereon. The sensing electrodes 540 and 541 may be insulated with the second sensing insulating layer 510 therebetween, and some may be electrically connected through an opening arranged in the sensing insulating layer 510. The sensing electrodes 540 and 541 may each independently include a metal such as aluminum (Al), copper (Cu), silver (Ag), gold (Au), molybdenum (Mo), titanium (Ti), or tantalum (Ta), or any metal alloy thereof, may be a single layer or a multilayer. A third sensing insulating layer 511 is formed on the sensing electrode 540.

The light blocking linear patterns BL are formed on the third sensing insulating layer 511. For example, the upper transparent organic layer TOL and the light blocking linear patterns BL are arranged on the third sensing insulating layer 511, the low-refractive layer VC is arranged on the upper portion of the light blocking linear pattern BL, and the reflective layer RL is arranged between the light blocking linear pattern BL and the upper transparent organic layer TOL and between the low-refractive layer VC and the upper transparent organic layer TOL. The reflective layer RL may be arranged between the third sensing insulating layer 511 and the light blocking linear pattern BL.

No additional light blocking layers, color filters, and/or color converting layers may be formed because of the light blocking linear patterns BL. However, depending on embodiments, if needed, they may be additionally formed on the upper portion or the lower portion of the light blocking linear patterns BL.

Depending on embodiments, in one or more embodiments, a polarizer may be included in the upper portion of the light blocking linear patterns BL. However, the polarizer may not be used in embodiments in which the pixel defining layer 380 includes a black pigment.

In one or more embodiments, the light blocking linear patterns BL, the reflective layer RL, the low-refractive layer VC, and the upper transparent organic layer TOL may be covered with an organic layer (or a planarization layer) to planarize the front surface of the light emitting display device.

FIG. 17 shows an embodiment in which three organic layers (181, 182, 183) are formed, and anode connecting openings are formed in the second organic layer and the third organic layer. However, in one or more embodiments, at least two organic layers may be formed, and the anode connecting opening may be arranged in an upper organic layer arranged far from the substrate, and a lower organic layer openings may be arranged in a lower organic layer.

According to one or more embodiments of the present disclosure, the display device may be applied to one or more electronic devices. The electronic device may include one or more selected from among televisions, monitors, outside billboards, personal computers, laptop computers, personal digital terminals, display devices for automobiles, game consoles, portable electronic devices, Internet of Things devices, cameras, mobile phones, smartphones, tablet computers, mobile communication terminals, electronic notebooks, electronic books, portable multimedia players, navigation devices, ultra-mobile personal computers, smartwatches, watch phones, head-mounted display devices, virtual reality devices, mixed reality devices, and augmented reality devices.

In the present disclosure, the term “refractive index” may refer to the refractive index of a material measured with respect to light have a wavelength of 589 nm.

In the context of the present disclosure and unless otherwise defined, the terms “use,” “using,” and “used” may be considered synonymous with the terms “utilize,” “utilizing,” and “utilized,” respectively.

In the present disclosure, the terms “at least any one of A, B, and C,” “at least any one of A, B, or C,” “at least any one selected from among A, B, and C,” and “at least any one selected from the group consisting of A, B, and C” may be construed as each of A, B, and C or a (e.g., any suitable) combination of two or more of A, B, and C (for example, ABC, ABB, BC, and CC). As used herein, “and/or” or “or” may include one or more combinations of corresponding components.

It will be understood that, although the terms “first,” “second,” “third,” and so on may be used herein to describe one or more suitable elements, these elements are not limited by these terms. These terms are used to distinguish one element from another element. Thus, a first element described could also be termed as a second or third element without departing from the spirit and scope of the disclosure. As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, the vehicle, the electronic devices/apparatus, the light blocking linear patterns/display device-manufacturing apparatus, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

While this disclosure has been described in connection with what is presently considered to be example embodiments, it is to be understood that the disclosure is not limited to the disclosed embodiments, but, on the contrary, is intended to cover one or more suitable modifications and equivalent arrangements included within the spirit and scope of the appended claims and equivalents thereof.

### REFERENCE NUMERALS AND REFERENCE LETTERS

110: substrate DD1, DD2: light emitting display device
EML, EMLr, EMLg, EMLb: light emitting layer
BL, BL′: light blocking linear pattern
TOL: upper transparent organic layer
BL-1: main body BL-2: protruding portion
RL: reflective layer
VC: low-refractive layer VC-1: first portion of the low-refractive layer
VC-2: second portion of the low-refractive layer
SP: scatterers
380: pixel defining layer OP3, OP4: opening
OP, OPr, OPg, OPb: opening of the pixel defining layer
Anode: anode Cathode: cathode
400: encapsulation layer 401: lower inorganic encapsulation layer
402: organic encapsulation layer 403: upper inorganic encapsulation layer
111: buffer layer 141, 142, 143: gate insulating layer 161, 162: interlayer insulating layer
181, 182, 183: organic layer
385, 385-1, 385-2: spacer 501, 510, 511: sensing insulating layer
540, 541: sensing electrode ACM2: anode connecting electrode
ACT1 (P—Si), ACT2 (IGZO): semiconductor layer
BML: metal layer FL: function layer
GAT2 (BML): lower shielding layer
HM: hard mask

What is claimed is:

1. A display device comprising:
a substrate;
a light emitting diode on the substrate and comprising a light emitting layer;
a pixel defining layer having an opening corresponding to the light emitting layer;
an encapsulation layer on an upper portion of the pixel defining layer and the light emitting layer;
light blocking linear patterns on an upper portion of the encapsulation layer, the light blocking linear patterns extending in a first direction, and each of light blocking linear patterns comprising a protruding portion;
a first organic layer between adjacent light blocking linear patterns; and
a second organic layer covering upper surfaces of the light blocking linear patterns and having a lower refractive index than the first organic layer.

2. The display device of claim 1, wherein
the light blocking linear patterns comprise a main body and the protruding portion, the main body and the protruding portion respectively having a columnar shape, and the protruding portion being on a portion of an upper surface of the main body, and
at least one of the light blocking linear patterns crosses the light emitting layer and overlaps the light emitting layer in a plan view.

3. The display device of claim 2, wherein
the protruding portion has a height of equal to or greater than about 1 μm and equal to or less than about 5 μm and has a height of equal to or greater than about ¼ and equal to or less than about ¾ of an entire height of a corresponding light blocking linear pattern of the light blocking linear patterns, and the protruding portion has a width of equal to or greater than about ¼ and equal to or less than about ¾ of a width of the main body.

4. The display device of claim 2, wherein
the second organic layer comprises a first portion and a second portion,
the first portion has the same width as the main body of a corresponding light blocking linear pattern of the light blocking linear patterns, and is on an upper surface of the protruding portion of the light blocking linear pattern, and
the second portion protrudes towards the substrate from the first portion corresponding to the protruding portion.

5. The display device of claim 4, wherein
the first organic layer has a refractive index of greater than 1.5, and the second organic layer has the refractive index of equal to or less than 1.5.

6. The display device of claim 4, wherein
a height of the main body of the light blocking linear pattern is equal to or greater than about 4 μm and equal to or less than about 30 μm, and an entire height of the light blocking linear pattern up to the protruding portion is equal to or greater than about 5 μm and equal to or less than about 35 μm,
an entire height of the second organic layer up to the second portion is equal to or greater than about 6 μm and equal to or less than about 10 μm, and a height of the first portion of the second organic layer is equal to or greater than 0 and equal to or less than about 5 μm,
an entire height of the first organic layer is equal to or greater than about 10 μm and equal to or less than about 40 μm,
a width of the main body of the light blocking linear pattern is equal to or greater than about 1 μm and equal to or less than about 5 μm, and a width of the first organic layer is equal to or greater than about 4 μm and equal to or less than about 10 μm, and
a width of a portion on which the first organic layer is arranged to a width of a portion on which the first organic layer is not arranged has a ratio of equal to or greater than 3:1 and equal to or less than 5:1.

7. The display device of claim 4, wherein
the second organic layer further comprises scatterers with a different refractive index from that of the second organic layer, and
the scatterers comprise at least one of titanium dioxide (TiO₂), silicon dioxide (SiO₂), zirconium oxide (ZrO₂), aluminum oxide (Al₂O₃), hollow silica, an acrylate-based material, or a silicon-based material.

8. The display device of claim 4, further comprising
a reflective layer between the light blocking linear pattern and the first organic layer and between the second organic layer and the first organic layer,
wherein the reflective layer has a thickness of equal to or greater than about 200 Å and equal to or less than about 500 Å.

9. The display device of claim 8, wherein
the reflective layer is on a bottom surface of the light blocking linear pattern.

10. The display device of claim 8, wherein
the reflective layer has a protruding structure higher than an upper surface of the second organic layer or an upper surface of the first organic layer.

11. A method comprising:
forming a first organic layer on a substrate on which an encapsulation layer is formed, the first organic layer being an upper transparent layer;
forming a hard mask pattern on the upper transparent layer;
forming an opening in the first organic layer by etching the first organic layer exposed by the hard mask pattern;
forming a reflective layer in the opening of the first organic layer by a chemical vapor deposition method;
removing the hard mask pattern;
forming a light blocking linear pattern comprising a protruding portion with an organic material comprising a black pigment on the reflective layer formed in the opening of the first organic layer; and
forming a second organic layer in the opening of the first organic layer and on an upper portion of the light blocking linear pattern,
wherein the method is a method for manufacturing a display device.

12. The method of claim 11, wherein
the light blocking linear pattern provides different exposed amounts depending on positions of the organic material, and is developed to comprise a protruding portion.

13. The method of claim 11, wherein
in the forming of the reflective layer, the reflective layer is formed on the hard mask pattern, and
in the removing of the hard mask pattern, the reflective layer on the hard mask pattern is removed together with the hard mask pattern.

14. The method of claim 11, wherein
the light blocking linear pattern comprises a main body and the protruding portion, the main body and the protruding portion each having a columnar shape, and the protruding portion being on a portion of an upper surface of the main body,
the second organic layer comprises a first portion and a second portion,
the first portion has the same width as the main body of the light blocking linear pattern, and is on an upper surface of the protruding portion of the light blocking linear pattern,
the second portion protrudes downward from the first portion corresponding to the protruding portion, and
the reflective layer is between the light blocking linear pattern and the first organic layer, between the second organic layer and the first organic layer, and on a bottom surface of the light blocking linear pattern.

15. An electronic device, comprising a light emitting display device,
wherein the light emitting display device comprises:
a substrate;
a light emitting diode on the substrate and comprising a light emitting layer;
a pixel defining layer having an opening corresponding to the light emitting layer;
an encapsulation layer on an upper portion of the pixel defining layer and the light emitting layer;
light blocking linear patterns on an upper portion of the encapsulation layer, the light blocking linear patterns extending in a first direction, and each of the light blocking linear patterns comprising a protruding portion;
a first organic layer between adjacent light blocking linear patterns; and
a second organic layer covering upper surfaces of the light blocking linear patterns and having a lower refractive index than the first organic layer.

16. The electronic device of claim 15, wherein
the electronic device further comprises a second light emitting display device, and
the second light emitting display device comprises:
a substrate;
a light emitting diode on the substrate and comprising a light emitting layer;
a pixel defining layer having an opening corresponding to the light emitting layer;
an encapsulation layer on an upper portion of the pixel defining layer and the light emitting layer;
second light blocking linear patterns on an upper portion of the encapsulation layer, the second light blocking linear patterns extending in a second direction that is different from the first direction, each of the second light blocking linear patterns comprising a protruding portion;
a first organic layer between adjacent second light blocking linear patterns; and
a second organic layer covering upper surfaces of the second light blocking linear patterns and having a lower refractive index than the first organic layer.

17. The electronic device of claim 15, wherein
the light blocking linear patterns each comprise a main body and the protruding portion, the main body and the protruding portion each having a columnar shape, and the protruding portion being on a portion of an upper surface of the main body,
at least one of the light blocking linear patterns crosses the light emitting layer and overlaps the light emitting layer in a plan view,
the second organic layer comprises a first portion and a second portion,
the first portion has the same width as the main body of a corresponding light blocking linear pattern of the light blocking linear patterns, and being on an upper surface of the protruding portion of the corresponding light blocking linear pattern, and
the second portion protrudes downward from the first portion corresponding to the protruding portion.

18. The electronic device of claim 17, wherein
the protruding portion has a height of equal to or greater than about 1 μm and equal to or less than about 5 μm, and has a height of equal to or greater than about ¼ and equal to or less than about ¾ of an entire height of a corresponding light blocking linear patter of the light blocking linear patterns, and the protruding portion has a width of equal to or greater than about ¼ and equal to or less than about ¾ of a width of the main body,
a height of the main body of the light blocking linear pattern is equal to or greater than about 4 μm and equal to or less than about 30 μm, and the entire height of the light blocking linear pattern up to the protruding portion is equal to or greater than about 5 μm and equal to or less than about 35 μm,
an entire height of the second organic layer up to the second portion is equal to or greater than about 6 μm and equal to or less than about 10 μm, and a height of the first portion of the second organic layer is equal to or greater than 0 and equal to or less than about 5 μm,
an entire height of the first organic layer is equal to or greater than about 10 μm and equal to or less than about 40 μm,
a width of the main body of the light blocking linear pattern is equal to or greater than about 1 μm and equal to or less than about 5 μm, and a width of the first organic layer is equal to or greater than about 4 μm and equal to or less than about 10 μm, and
a width of a portion on which the first organic layer is arranged to a width of a portion on which the first organic layer is not arranged has a ratio of equal to or greater than 3:1 and equal to or less than 5:1.

19. The electronic device of claim 15, further comprising
a reflective layer between the light blocking linear pattern and the first organic layer and between the second organic layer and the first organic layer,
wherein the reflective layer has a thickness of equal to or greater than about 200 Å and equal to or less than about 500 Å.

20. The electronic device of claim 15, wherein
the second organic layer further comprises scatterers with a refractive index that is different from a refractive index of the second organic layer, and
the scatterers comprise at least one of titanium dioxide (TiO₂), silicon dioxide (SiO₂), zirconium oxide (ZrO₂), aluminum oxide (Al₂O₃), hollow silica, an acrylate-based material, or a silicon-based material.
